(19) United States
(12) Patent Application Publication
(10) Pub. No.: US 2006/0236168 A1
(43) Pub. Date: Oct. 19, 2006

(54) System and method for dynamically optimizing performance and reliability of redundant processing systems

(75) Inventors: Jeffrey M. Wolfe, Parrish, FL (US); Jason L. Copenhaver, Sarasota, FL (US); Jeremy Ramos, Clearwater, FL (US)

Correspondence Address: HONEYWELL INTERNATIONAL INC., 101 COLUMBIA ROAD, P O BOX 2245, MORRISTOWN, NJ, 07962-2245, US

(73) Assignee: HONEYWELL INTERNATIONAL INC., MORRISTOWN, NJ (US)

(21) Appl. No.: 11/096,872

(22) Filed: Apr. 1, 2005

(51) Int. Cl. G01R 31/28

(52) U.S. Cl. 714/724

(57) ABSTRACT

An improved system and method for dynamically optimizing the performance and reliability of redundant processing systems (e.g., for use in space applications) are disclosed. As one example, a Field Programmable Gate Array (FPGA) that includes a plurality of processors is disclosed. Based on mission specific modes or environmental conditions, the processing system can dynamically and safely transition between the high performance of, for example, a general purpose, quad Symmetric Multiprocessor (SMP) and the high reliability of a redundant set of processors (e.g., Triple Modular Redundancy system). This architecture allows the use of a single FPGA with multiple processors to take advantage of the maximum processing throughput available when sufficient mission conditions are met, and can also safely transition to a lower throughput, high reliability mode when needed. In other words, at particular points during a mission, high processing capacity and throughput can be obtained at the expense of reliability or dependability as the mission conditions allow. If the mission conditions can support a reduced level of dependability at a particular point in time, then the processors can be adapted to run in a single string (e.g., triple or quad string) to produce three to four times the processing capacity of the redundant set.

### RELATED APPLICATION

The present application is related to commonly assigned U.S. patent application Ser. No. 10/867,894 (Attorney Docket No. H0006620-1628) entitled “REDUNDANT PROCESSING ARCHITECTURE FOR SINGLE FAULT TOLERANCE”, filed on Jun. 15, 2004, which is incorporated herein by reference in its entirety.

### FIELD OF THE INVENTION

The present invention relates generally to the computer processing field, and more specifically, but not exclusively, to a system and method for dynamically optimizing the performance and reliability of redundant processing systems that can be used, for example, in space applications.

### BACKGROUND OF THE INVENTION

In space applications, there is a significant need for smaller and lighter, lower power consuming, high performance systems with increased reliability and higher processing speeds. In order to be cost-effective, these systems are typically designed to minimize their size and weight, because size and weight are typically the overriding “costs” in space missions. Nevertheless, in space applications, mission-critical components of systems are duplicated in order to increase their reliability and tolerance to faults. For example, multiple processors operating as a redundant set are designed to receive the same input data, perform the same mission-critical computations, and transmit the same output commands. However, in addition to the need for increased reliability and tolerance to faults for systems operating in space, there is also a significant need for increased throughput or processing speed. However, the processing speeds of the hardware on existing space systems are relatively slow, and (due partly to their need for redundancy and fault tolerance) these systems are relatively expensive. Therefore, there is a significant need for a technique that can optimize the performance and reliability of redundant processing systems, which can be used, for example, in space applications without incurring significant additional costs. As described in detail below, the present invention provides such a technique, with a system and method that dynamically optimizes performance and reliability in redundant processing systems.

### SUMMARY OF THE INVENTION

The present invention provides an improved system and method for dynamically optimizing the performance and reliability of redundant processing systems (e.g., for use in space applications). In accordance with a preferred embodiment of the present invention, a Field Programmable Gate Array (FPGA) is provided that includes a plurality of processors. Based on mission specific modes or environmental conditions, the processing system can dynamically and safely transition between the high performance of, for example, a general purpose, quad Symmetric Multiprocessor (SMP) and the high reliability of a redundant set of processors (e.g., Triple Modular Redundancy (TMR) system). This architecture allows the use of a single FPGA with multiple processors to take advantage of the maximum processing throughput available when sufficient mission conditions are met, and can also safely transition to a lower throughput, high reliability mode when needed. In other words, at particular points during a mission, high throughput or processing capacity can be obtained at the expense of reliability or dependability as the mission conditions allow. If the mission conditions can support a reduced level of dependability at a particular point in time, then the processors can be adapted to run in a single string (e.g., triple or quad string) to produce three to four times the processing capacity of the redundant set.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 depicts a block diagram of a system that can be used to implement a preferred embodiment of the present invention;

FIG. 2 depicts a block diagram of an example comparator unit, which can be used to implement comparator unit 104 in FIG. 1;

FIG. 3 depicts an example graphical representation of processing capacity versus dependability for a plurality of processors over time, which illustrates principles of the present invention; and

FIG. 4 depicts a flow chart of an example method that can be used to implement a preferred embodiment of the present invention.

### DETAILED DESCRIPTION OF PREFERRED EMBODIMENT

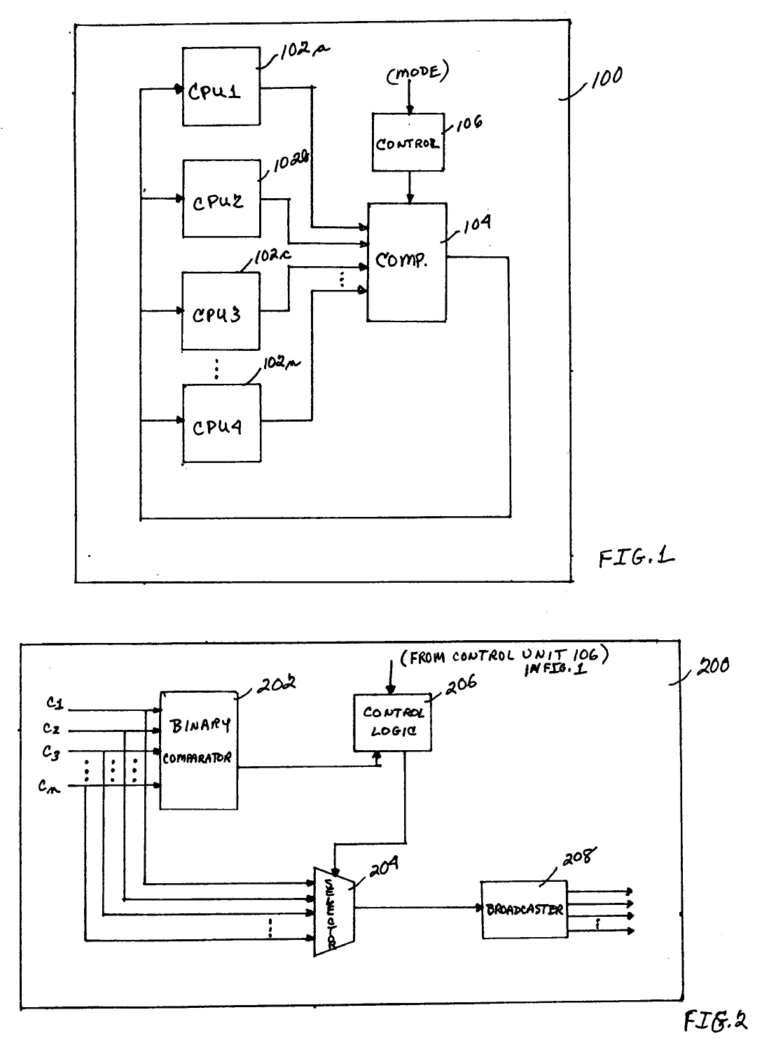

With reference now to the figures, FIG. 1 depicts a block diagram of a system 100 that can be used to implement a preferred embodiment of the present invention. In one embodiment, system 100 can be an electronic component in an Application Specific Integrated Circuit (ASIC). In another embodiment, system 100 can be an electronic component in a Printed Wire Assembly (PWA). For this exemplary embodiment, system 100 is preferably a logic device including at least one Field-Programmable Gate Array (FPGA). However, it should be understood that the present invention is not intended to be so limited, and can include, for example, any suitable system, circuit, integrated circuit, chip, electronic component, electronic module, etc., which includes a plurality of processing units in a redundant set and is capable of operating in a space mission or similar environment.

For this illustrative example, system 100 includes a plurality of processing units 102a, 102b, 102c, . . . 102n (wherein the suffix “n” denotes the total number of processing units being used), a comparator unit 104, and a control unit 106. As such, although four processing units 102a-102n are shown in this example, this particular number is for illustrative purposes only and any suitable number of processing units may be used in system 100. However, if processing units 102a-102n are intended for use in a redundant, fault tolerant architecture, then it is preferable that system 100 include at least three redundant processing units. For example, as disclosed in the above-described, related application entitled “REDUNDANT PROCESSING ARCHITECTURE FOR SINGLE FAULT TOLERANCE”, the inclusion of a third processing unit provides a tie-breaking vote in determining a faulty processing unit. In any event, an example of a suitable logic device including a plurality of processors and a comparator, which can be used to implement at least a portion of system 100 arranged as a logic device including a plurality of processing units (e.g., processing units 102a-102n) and a comparator unit (e.g., 104), is the Virtex-II Pro® FPGA manufactured by Xilinx, Inc. The Virtex-II Pro FPGA is a Programmable Logic Device (PLD), which can include up to four, on-chip 300-400 MHz, 420+ DMIPS IBM PowerPC® 405 processors, with on-chip memory and programmable logic resources appropriately coupled to maximize performance.

Notably, instead of a single logic device including four processing units and a comparator unit, the present invention is not intended to be limited by such an architecture and can be arranged in a different embodiment as, for example, two logic devices that include two processors and one comparator in each. In such an arrangement, the two comparators can be combined to perform the comparison function in a distributed architecture. As such, in one embodiment, both comparators can perform substantially the same comparison function. In another embodiment, the two comparators can complement each other and together perform the one comparison function.

For this example embodiment, an output of each processing unit 102a-102n is coupled to a respective input of comparator unit 104. Also, an output of comparator unit 104 is coupled to an input of each processing unit 102a-102n. For this example, comparator unit 104 is implemented advantageously as a hardware comparator, as opposed to being implemented in software (e.g., speed of hardware implementation is significantly faster than software implementation). Thus, comparator unit 104 can perform a comparison function with respect to the input data received from each processing unit 102a-102n, and responsive to the results of comparison functions performed, comparator unit 104 can output one or more suitable signals to control an operation of each processing unit 102a-102n. Additionally, however, comparator unit 104 can also output suitable signals to control the operation of each processing unit 102a-102n responsive to one or more control signals received from an output of the control unit 106.

FIG. 2 depicts a block diagram of an example comparator unit 200, which can be used to implement comparator unit 104 in FIG. 1. For this example embodiment, comparator unit 200 includes a binary comparator 202, a selector 204, a control logic unit 206, and a broadcaster 208. A plurality of inputs C₁-Cn for binary comparator 202 are arranged to receive signals output from respective outputs of processing units (not shown), such as, for example, processing units 102a-102n in FIG. 1. Also, inputs C₁-Cn are coupled to respective inputs of selector 204. An output of binary comparator 202 is coupled to control logic unit 206, and an output of control logic unit 206 is coupled to a selection input of selector 204. An output of selector 204 is coupled to an input of broadcaster 208. Notably, for this example embodiment, a second input of control logic unit 206 is coupled to an output of an external control unit (e.g., control unit 106 in FIG. 1).

In operation, for this example embodiment, each processing unit 102a-102n in FIG. 1 generates a respective output signal C₁-Cₙ. The output signals C1-Cn are received by binary comparator 202. Binary comparator 202 can perform a bit-level comparison to detect any change in bit positions between processor outputs, in order to determine if there is a faulty or failed processor. The result of the bit comparison in binary comparator 202 is forwarded to control logic unit 206. Control logic unit 206 generates a control signal based on the comparison results. The control signal from control logic unit 206 triggers selector 204. In the event of a failed processor, a control signal from control logic unit 206 triggers selector 204 to choose an output other than the failed output to be sent to broadcaster 208. Broadcaster 208 broadcasts the selected signal to all of the processing units (e.g., processing units 102a-102n), and the failed processor can be reset in response.

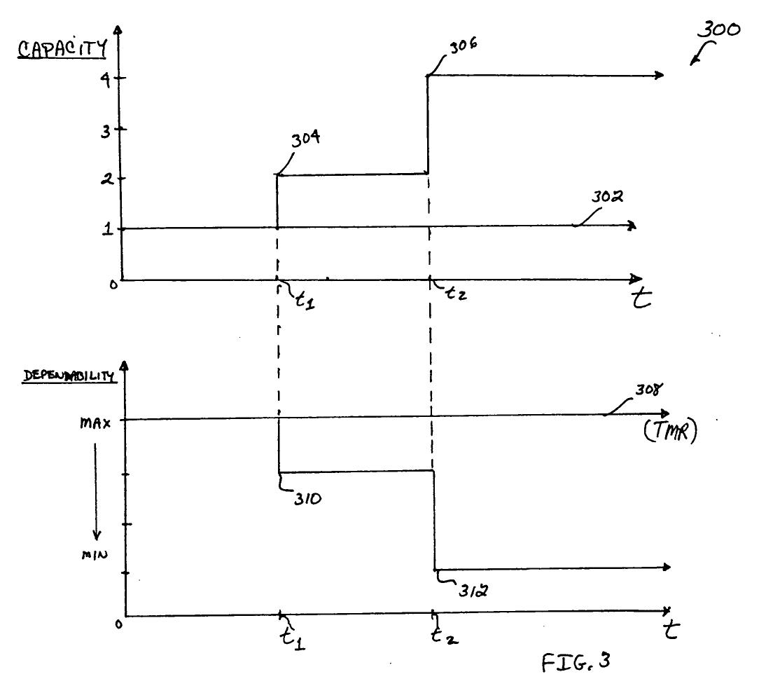

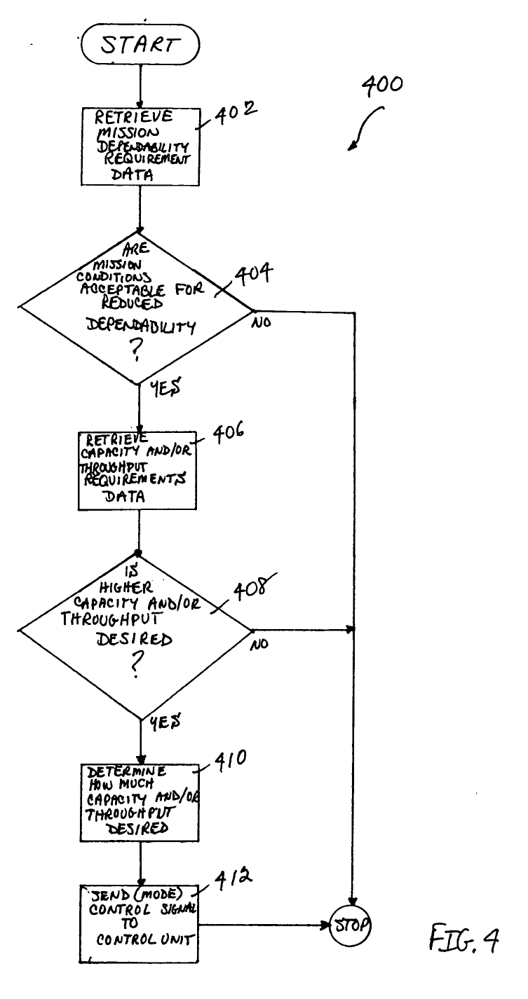

Notably, however, in accordance with the principles of the present invention, control logic unit 206 can also generate a control signal to trigger selector 204 to choose a suitable output for broadcaster 208, which is responsive to an input signal received from the external control unit (e.g., control unit 106 in FIG. 1). Broadcaster 208 can then broadcast the selected output signal to all of the processing units (e.g., processing units 102a-102n) in order to configure the processing units according to mission needs. For illustrative purposes in this example, it can be assumed that processing units 102a-102n in FIG. 1 are operating initially as a redundant set of four processors in order to achieve greater redundancy and higher fault tolerance. As such, for this example, the fully redundant set of processing units 102a-102n can represent what is known as the “maximal solution” or standard ASIC TMR solution. Consequently, with the maximal or TMR solution, the processing capacity of the redundant set of processing units 102a-102n can be associated with a particular level of dependability. In other words, with a fully redundant set of processors in the maximal or TMR solution, the processing capacity for the set remains constant throughout a mission. An example that illustrates this relationship between processing capacity and dependability is described below with respect to FIG. 3.

FIG. 3 depicts an example graphical representation 300 of processing capacity versus dependability for a plurality of processors over time, which illustrates principles of the present invention. For illustrative purposes in this example, it may be assumed that the overall time period, t, depicted in FIG. 3 represents the elapsed time of a space mission. Referring now to FIGS. 1 and 3, it can be seen that a particular level of processing capacity (e.g., fully redundant set having capacity of 1 processor) 302 is constant over time, t, for a maximum level of dependability (e.g., the maximal or TMR solution) 308. However, for this example, it may also be assumed that as the mission progresses in time, the mission conditions are such that a reduced level of processing dependability is acceptable at time, t₁. So, at time, t₁, control unit 106 in FIG. 1 (e.g., responsive to a mission system direction) can output a control signal (e.g., composed of four bits) to comparator 104, which in turn, outputs suitable control signals (e.g., composed of four words, or one word for each processor involved) to processing units 102a-102n to reconfigure to a reduced redundant set. For example, as indicated by the increased processor capacity level 304 at time, t₁, comparator 104 can direct the redundant set of three processing units (e.g., 102a-102c) to be operated in a string with the fourth processing unit (102n in this example) to provide increased throughput, but the level of processing dependability at time, t₁, (e.g., indicated as 310) is decreased. Similarly, depending on the mission requirements, if the mission continues and the conditions are such that an additional reduction in the level of dependability is acceptable, then control unit 106 can output a control signal to comparator 104, which in turn, outputs suitable signals to processing units 102a-102n to reconfigure, for this example, to a high performance, quad SMP configuration (e.g., string of four processing units) to produce a maximum level of processing capacity (and throughput), as indicated by the processing capacity level 306 at time, t₂. However, also at time, t₂, the quad SMP configuration of processing units 102a-102n provides a minimum possible level of dependability, as indicated by the decreased dependability level 312.

As such, FIG. 3 illustrates that mission conditions at particular times may be acceptable for different processing unit configurations, in order to dynamically optimize the processing capacity and dependability of system 100. For example, mission conditions may be acceptable for decreasing or increasing processing system dependability by transitioning safely and smoothly between different processor configurations, such as, for example, a quad string processor configuration, a triple redundant plus one processor configuration, a dual redundant plus two processors configuration, two dual redundant processors configuration, and a fully redundant maximal or TMR solution configuration. Notably, although processor configuration can be used for dynamically optimizing system capacity and dependability, the present invention is not intended to be so limited and can also include the reconfiguration of one or more processing units on a task basis.

For example, a particular software task in a mission application may not require maximum dependability, so control unit 106 can be directed to output suitable control signals (e.g., via comparator 104) to reconfigure processing units 102a-102n responsive to the reduced need for dependability (e.g., to increase throughput for this task). Thus, in accordance with the principles of the present invention, system 100 can dynamically reconfigure the redundant set of processing units 102a-102n in order to optimize the dependability or reliability and capacity and throughput of the processing units responsive to changing mission conditions, with a relatively small and readily configurable logic device.

FIG. 4 depicts a flow chart of an example method 400 that can be used to implement a preferred embodiment of the present invention. For this example embodiment, a processor (not explicitly shown) associated with, or included in, a control unit (e.g., control unit 106 in FIG. 1) can be responsible for monitoring performance related conditions throughout a mission (e.g., onboard or external processor for a space mission). For this example, as the mission progresses, this mission processor retrieves dependability requirements for the mission applications (or mission processor tasks) to be run during a predetermined time period (step 402). The mission processor (or control unit, itself) then determines whether or not the mission conditions (e.g., dependability requirements) are such that a reduced level of dependability may be acceptable for the predetermined time period (step 404). For example, it may be assumed that initially processing units 102a-102n are being operated in a fully redundant mode (e.g., to obtain the maximal or TMR solution system) for maximum potential dependability and increased fault tolerance. If the projected mission conditions are not deemed acceptable to allow reduced dependability for the predetermined time period, then the flow is stopped.

If (at step 404), however, the mission processor (or the control unit) determines that the projected mission conditions for the predetermined time period are such that a reduced level of processor dependability is acceptable, then the mission processor retrieves capacity and/or throughput requirements for the mission application(s) and/or processing tasks that are to be (or are being) run during the predetermined time period (step 406). The mission processor (or control unit) then determines whether or not additional processor capacity and/or throughput are desired for the predetermined time period (step 408). If not, then the flow is stopped.

If (at step 408), however, the mission processor (or the control unit) determines that additional processor capacity and/or throughput are desired for the predetermined time period, then the mission processor (or the control unit) determines what amount of additional capacity and/or throughput are desired (step 410). The mission processor (or the control unit, itself) then generates a (mode) control signal that includes appropriate control data for reconfiguring the arrangement of the processing units involved (e.g., processing units 102a-102n), in order to attain the desired increase in processing capacity and/or throughput desired (e.g., or at least as much additional processing capacity and/or throughput possible). The (mode) control signal is then sent to the (mode) control unit (e.g., control unit 106) or, in the embodiment illustrated by FIGS. 1 and 2, to the selector 204 for implementation (step 412). For example, the (mode) control signal may cause selector 204 to configure processing units 102a-102n as a triple or quad (SMP) string of processing units, in order to achieve up to 3 or 4 times the processing capacity and/or throughput of the redundant set. The flow can then be stopped.

It is important to note that while the present invention has been described in the context of a fully functioning processing system, those of ordinary skill in the art will appreciate that the processes of the present invention are capable of being distributed in the form of a computer readable medium of instructions and a variety of forms and that the present invention applies equally regardless of the particular type of signal bearing media actually used to carry out the distribution. Examples of computer readable media include recordable-type media, such as a floppy disk, a hard disk drive, a RAM, CD-ROMs, DVD-ROMs, and transmission-type media, such as digital and analog communications links, wired or wireless communications links using transmission forms, such as, for example, radio frequency and light wave transmissions. The computer readable media may take the form of coded formats that are decoded for actual use in a particular processing system.

The description of the present invention has been presented for purposes of illustration and description, and is not intended to be exhaustive or limited to the invention in the form disclosed. Many modifications and variations will be apparent to those of ordinary skill in the art. These embodiments were chosen and described in order to best explain the principles of the invention, the practical application, and to enable others of ordinary skill in the art to understand the invention for various embodiments with various modifications as are suited to the particular use contemplated.

What is claimed is:

1. A system, comprising:
a plurality of processing units;
at least one comparator unit coupled to said plurality of processing units; and
a control unit coupled to said at least one comparator unit, said at least one comparator unit operable to vary a processing capacity level associated with said plurality of processing units responsive to said control unit.

2. The system of claim 1, wherein said plurality of processing units are programmable processing units.

3. The system of claim 1, wherein said at least one comparator unit is programmable.

4. The system of claim 1, wherein said plurality of processing units are arranged in a Field-Programmable Gate Array.

5. The system of claim 1, wherein said plurality of processing units, said at least one comparator unit, and said control unit are arranged in a Field-Programmable Gate Array.

6. The system of claim 1, wherein said plurality of processing units and said at least one comparator unit are arranged in an Application-Specific Integrated Circuit.

7. The system of claim 1, wherein said plurality of processing units includes at least two processing units arranged as a redundant set.

8. A programmable logic device, comprising:
at least two processors, each processor of said at least two processors operable to perform substantially the same function; and
a control unit coupled to said at least two processors, wherein said control unit is operable to program said at least two processors such that said at least two processors are arranged in at least one of a string configuration or a redundant configuration.

9. The programmable logic device of claim 8, wherein the programmable logic device comprises a Field-Programmable Gate Array.

10. The programmable logic device of claim 8, wherein the programmable logic device comprises an integrated circuit.

11. The programmable logic device of claim 8, wherein the programmable logic device comprises a printed wire assembly.

12. A method for dynamically optimizing the performance and reliability of a redundant processing system, comprising the steps of:
retrieving at least one dependability requirement for a plurality of processors;
determining whether a reduced level of dependability is acceptable for said plurality of processors;
retrieving at least one capacity requirement for said plurality of processors;
determining whether an increased level of capacity is desired for said plurality of processors;
if an increased level of capacity is desired for said plurality of processors, and a reduced level of dependability is acceptable for said plurality of processors, sending a control signal to said plurality of processors; and
responsive to said control signal, increasing a processing capacity level for said plurality of processors.

13. The method of claim 12, wherein said plurality of processors are programmable processing units.

14. The method of claim 12, wherein said plurality of processors are arranged in a Field-Programmable Gate Array.

15. The method of claim 12, wherein the sending step is performed by a control unit arranged in a Field-Programmable Gate Array.

16. The method of claim 12, wherein the redundant processing system comprises at least three processing units.

17. The method of claim 12, wherein the increasing step further comprises the step of arranging a plurality of processing units as a serial string of processing units.

18. The method of claim 12, wherein the increasing step further comprises the step of arranging a plurality of processing units as a quad Symmetric Multiprocessor.

19. The method of claim 12, wherein the increasing step is performed by a hardware comparator and at least two processing units.

20. The method of claim 12, wherein the redundant processing system is arranged on a semiconductor chip.

21. A method for dynamically optimizing the performance and reliability of a redundant processing system, comprising the steps of:
retrieving at least one capacity requirement for a plurality of processors;
determining whether a reduced level of capacity is acceptable for said plurality of processors;
retrieving at least one dependability requirement for said plurality of processors;
determining whether an increased level of dependability is desired for said plurality of processors;
if an increased level of dependability is desired for said plurality of processors, and a reduced level of capacity is acceptable for said plurality of processors, sending a control signal to said plurality of processors; and
responsive to said control signal, increasing a processing dependability level for said plurality of processors.
